(19) United States
(12) Patent Application Publication
(10) Pub. No.: US 2010/0091436 A1
(43) Pub. Date: Apr. 15, 2010

(54) WALL MOUNTED DISPLAY DEVICE

(75) Inventors: Rolf Guldener, Uetikon am See (CH); Anton Werner Keller, Arni (CH)

Correspondence Address: Robert D. Shedd, Patent Operations;THOMSON Licensing LLC, P.O. Box 5312, Princeton, NJ, 08543-5312, US

(73) Assignee: THOMSON LICENSING, Princeton, NJ (US)

(21) Appl. No.: 12/451,529

(22) PCT Filed: May 23, 2007
(86) PCT No.: PCT/IB2007/001350

§ 371 Date: Nov. 17, 2009

(51) Int. Cl. H05K 7/00

(52) U.S. Cl. 361/679.01

(57) ABSTRACT

A wall mounted display device having user friendly connectors for coupling with one or more remote appliances is described. The wall mounted display includes a connector portion that is moveable with respect to the display device. The moveable connector portion is positioned along a portion of a side of the display device and provides easier access to connectors needed to couple a remote appliance to the display device. Alternatively, the screen of the display device is moveable with respect to a wall to which the display device is mounted. The screen is moveable in a plane substantially parallel with the wall upon which the display device is mounted, pivotable at an angle away from the wall upon which the display device is mounted, or rotatable with respect to an electronics portion of the display device.

### FIELD OF THE INVENTION

The invention is related generally to a display device, and more particularly to a wall mounted display device.

### BACKGROUND

As display devices have become thinner and thinner, e.g., less than about 13 cm in depth, it has become advantageous to mount such displays on a wall. Referring to FIG. 1, there is depicted one example of a wall mounted display device 10. Typically, the display device 10 is coupled to one or more remote appliances 12, 13, 14 (e.g., a video cassette recorder (VCR), a digital video disk (DVD) player, set top portion (STB), digital video recorder (DVR), etc.) which may provide content to be displayed on the display device 10.

Each appliance 12, 13, 14 is coupled to the display device 10 via one or more wires 16, 18, 20. Additionally, a power cord 22 provides power to the display device 10.

For many wall mounted display devices 10, the wiring 16, 18, 20, 22 often runs along the wall between the wall mounted display device 10 and the one or more appliances 12, 13, 14. One problem with coupling the one or more appliances 12, 13, 14 the display device is that the connectors (not shown) for connecting each appliance 12, 13, 14 to the wall mounted display device 10 may be inaccessible. For example, the connectors may be accessible only from the back of the display device, or the labeling may not be legible without the use of a mirror. Additionally, the wires 16, 18, 20, 22 running between the wall mounted display device 10 and the one or more appliances 12, 13, 14 may be displeasing to a viewer.

Thus, there is a need for a wall mounted display device having user friendly connectors for coupling with one or more appliances.

### SUMMARY OF THE INVENTION

The present invention is directed to a wall mounted display device having user friendly connectors for coupling with one or more remote appliances. In one embodiment, the wall mounted display includes a connector portion that is moveable with respect to the display device. The moveable connector portion is positioned along a portion of a side of the display device and provides easier access to connectors needed to couple a remote appliance to the display device.

Alternatively, the screen of the display device is moveable with respect to a wall to which the display device is mounted. In one embodiment the screen is moveable in a plane substantially parallel with the wall upon which the display device is mounted. The screen may be moveable in a vertical plane as well as in a horizontal plane with respect to the wall upon which the display device is mounted. The screen is moveable to provide front access to the connectors needed to couple a remote appliance to the display device.

In another embodiment, the screen is pivotable at an angle away from the wall upon which the display device is mounted. The screen is pivotable at an angle sufficient to provide front access to the connectors needed to couple a remote appliance to the display device.

In yet another embodiment, the screen is rotatable with respect to an electronics portion of the display device. The screen may be rotatable in a vertical plane with respect to the electronics portion of the display device. The screen is rotatable to provide front access to the connectors needed to couple a remote appliance to the display device.

### BRIEF DESCRIPTION OF THE DRAWINGS

The invention will now be described with reference to the accompanying figures of which:

FIG. 1 shows a diagrammatic view of a prior art wall mounted display device coupled to one or more remote appliances;

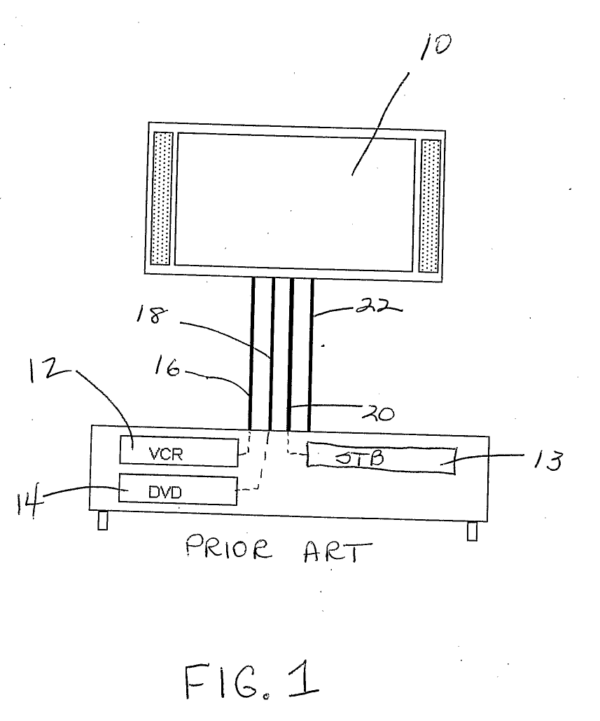

FIG. 2 shows a top view of the wall mounted display device having a moveable connector portion according to an exemplary embodiment of the invention;

FIGS. 3A-3B show enlarged top views of the moveable connector portion of FIG. 2 moveable with respect to the display device;

FIGS. 4A-4B show enlarged top views of the moveable connector portion of FIG. 2 that are moveable and pivotable with respect to the display device;

FIGS. 5A-5C show top and front views of the wall mounted display device having a moveable screen according to another exemplary embodiment of the invention;

FIG. 6 shows a top view of the wall mounted display device having a pivotable screen according to another exemplary embodiment of the invention;

FIGS. 7A-7B show top and front views of the wall mounted display device having a rotatable screen according to another exemplary embodiment of the invention;

FIGS. 8A-8B show top views of the wall mounted display device having connectors positioned for front access behind either the moveable screen of FIGS. 5A-5C or the pivotable screen of FIG. 6;

FIG. 9 shows a front view of the wall mounted display device having a conduit within which is hidden the wires coupling the display device with the remote appliances; and

FIGS. 10A-10B show enlarged top and front views of the conduit shown in FIG. 9.

### DETAILED DESCRIPTION

The present invention is directed to a wall mounted display device having user friendly connectors for coupling with one or more remote appliances. The connectors may be mounted to a side wall of the display device to have the wires/cables bundled naturally at one side of the display.

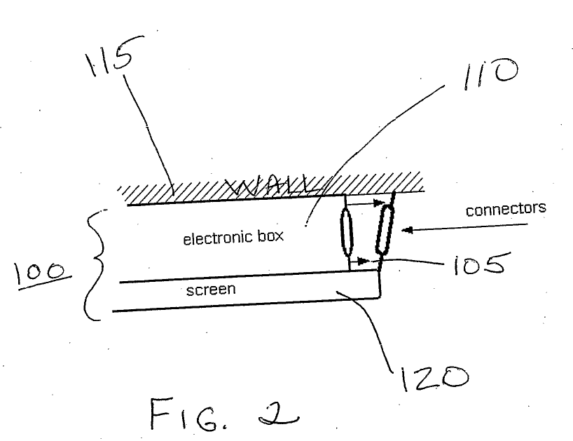

In one embodiment, the wall mounted display includes a connector portion that is moveable with respect to the display device. Referring to FIG. 2, a top view of the wall mounted display device 100 is shown. The wall mounted display device includes an electronic portion 110 and a screen 120 mounted on a wall 115 of a room. The electronic portion 110 includes electronic parts of the display device necessary to display images on the screen 120. The screen 110 may optionally include electronic parts, such as for example driver circuitry. The electronic portion 110 has a moveable connector portion 105 coupled thereto. The moveable connector portion 105 is preferably positioned along a portion of a horizontal side of the electronic portion 110 and provides easier access to connectors needed to couple one or more remote appliances to the display device 100. The moveable connector portion 105 may optionally be coupled to a vertical side wall of the display device.

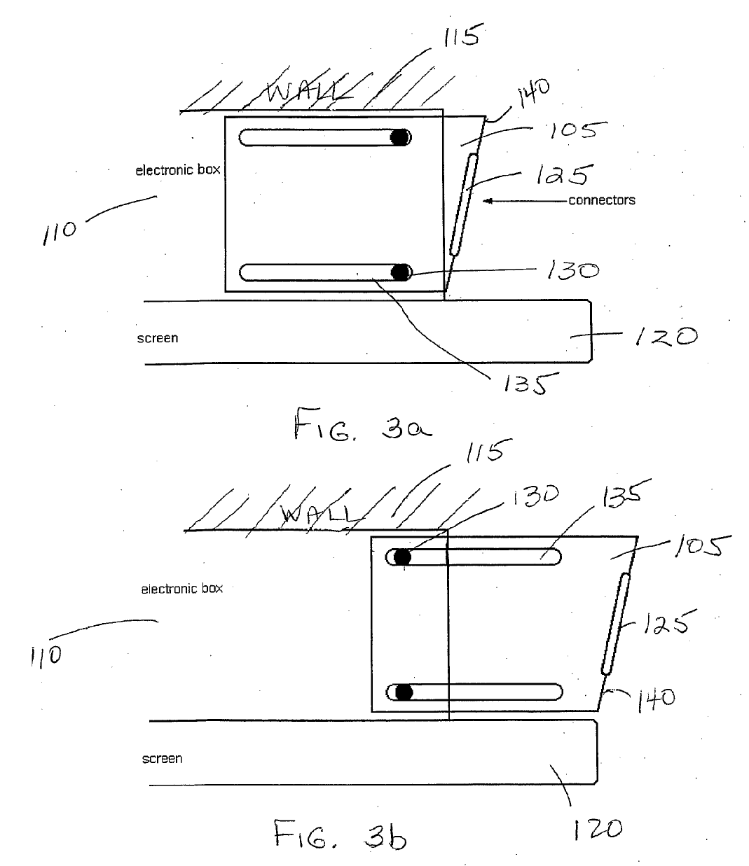

The moveable connector portion 105 may be moveable as shown in FIGS. 3A-3B. Referring to FIG. 3A, there is shown an enlarged section of the wall mounted display device depicted in FIG. 2. The moveable connector portion 105 houses a plurality of connectors 125 which may be used to couple the wall mounted display device 100 with one or more remote appliances (not shown).

The moveable connector portion 105 may be coupled to a top horizontal side of the electronic portion 110 (shown in FIG. 3A), the bottom horizontal side of the electronic portion 110, or between both the top horizontal side and the bottom horizontal side of the electronic portion 110. The moveable connector portion may alternatively be coupled to either of the vertical sides of the electronic portion 110, or between the vertical sides of the electronic portion 110.

The moveable connector portion 105 has at least one slot 135 through a side thereof. The electronic portion 110 has one or more openings 130 therein that correspond with the at least one slot 135 in the moveable connector portion 105. The moveable connector portion 105 may be coupled to the electronic portion 110 with a guiding member that guides the moveable connector portion 105 as it is moved. Suitable guiding members may include bolts, rollable pins, pegs, etc.

FIG. 3B depicts the moveable connector portion 105 extending away from the electronic portion 110 so as to make the connectors 125 accessible to a user. The moveable connector portion preferably moves so as to extend to an edge of the screen 120, as shown in FIG. 3B. A handle (not shown) may be coupled to the side 140 of the moveable connector portion 105 to facilitate the movement thereof.

The side 140 of the moveable connector portion 105 that extends to the edge of the screen may be tilted as shown in FIG. 3B, to provide easier access to the plurality of connectors 125. The side 140 of the moveable connector portion 105 may be tilted from the normal by about 10-15 degrees.

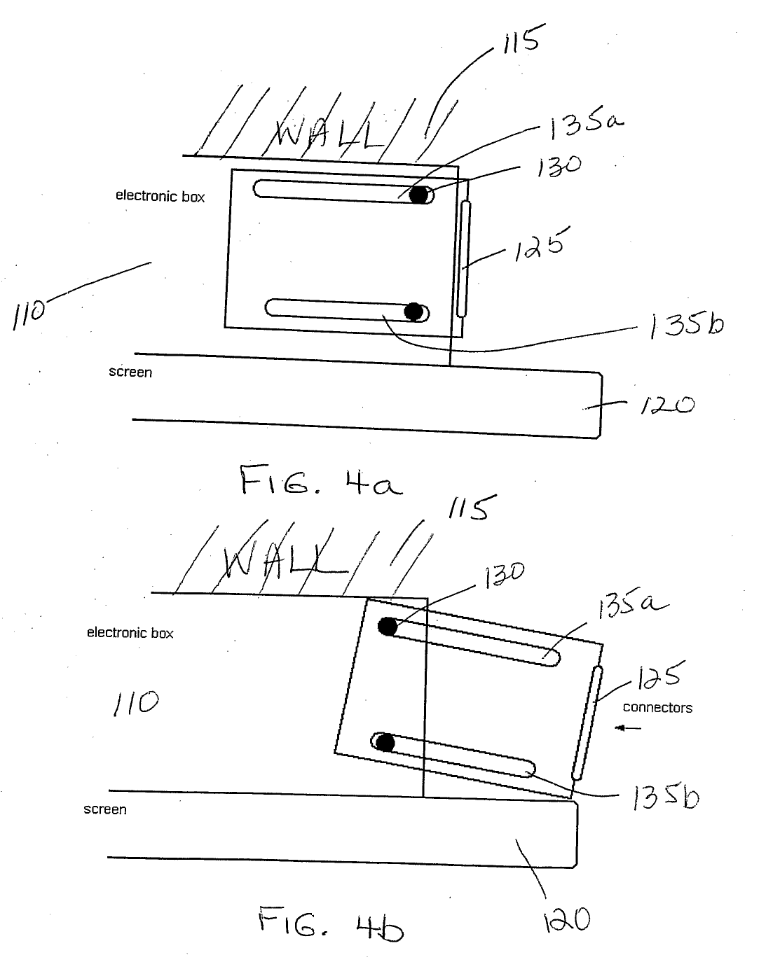

Referring to FIGS. 4A-4B, the moveable connector portion 105 may also be tiltable. In one embodiment, the moveable connector portion 105 may include two slots 135a, 135b through a side thereof. The slots 135a, 135b having different lengths, with the slot 135b closest to the screen 120 being shorter than the slot 135a closest to the wall 115. The relationship between the lengths of the two slots 135a, 135b enables the moveable connector portion 105 to be tilted towards the screen 120 so as to provide easier access to the plurality of connectors 125. The difference between the lengths of the two slots 135a, 135b should allow the moveable connector portion 105 to be tilted about 10-15 degrees when the connector portion 105 is extended to the edge of the screen 120.

In the above embodiments, the slots described are linear. Alternatively, the one or more slots may be curved (not shown), so that when the connector portion 105 is extended along their length such portion may be tilted. For curved slots, additional guiding members may be used to enhance the guiding along the at least one slot.

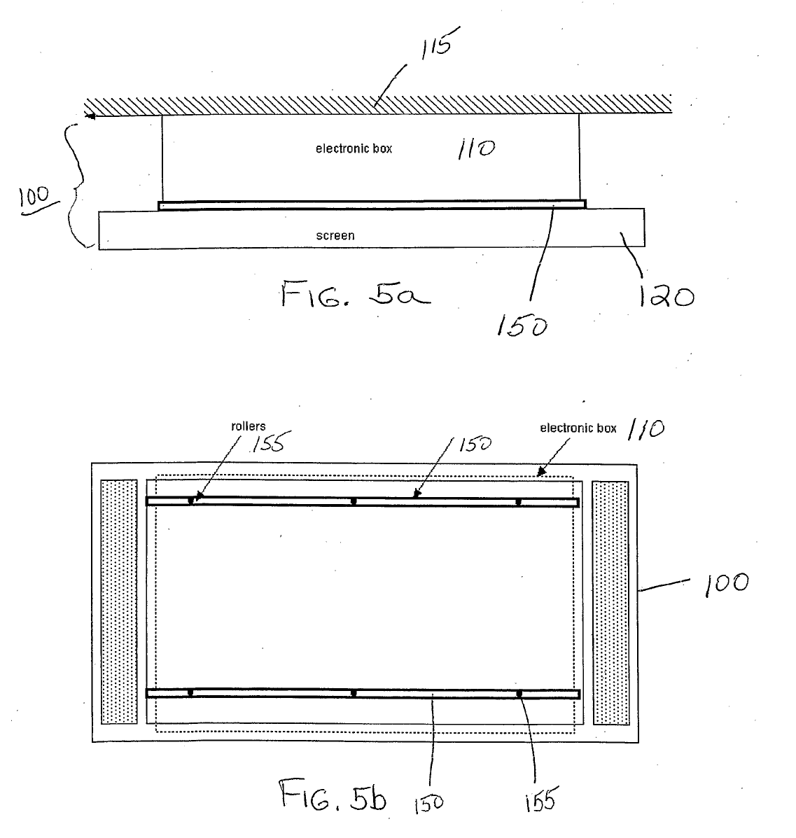

Referring to FIGS. 5A-5C, the screen of the display device may be moveable with respect to a wall to which the display device is mounted. In one embodiment, the screen is moveable in a plane substantially parallel with the wall upon which the display device is mounted. The screen may be moveable in a vertical plane as well as in a horizontal plane with respect to the wall upon which the display device is mounted. The screen is moveable to provide easier access to the connectors needed to couple a remote appliance to the display device.

Referring to FIG. 5A, a top view of the wall mounted display device 100 is shown. The wall mounted display device 100 includes an electronic portion 110 and a screen 120 mounted on a wall 115 of a room. The electronic portion 110 includes electronic parts of the display device necessary to display images on the screen 120. The electronic portion 110 has a plurality of connectors 125 coupled to a side thereof (FIG. 5C). The screen 120 is coupled to the electronic portion 110 with at least one elongate member 150 and rollers 155 (FIG. 5B). Alternatively, sliders, wheels or ball bearings may be used instead of rollers to provide easy movement along the at least one elongate member 150.

The screen 120 is moveable along the elongate member 150 so that easy access is provided to the plurality of connectors 125 coupled to the side of the electronic portion 110. The screen 120 is preferably moveable a distance sufficient to expose the side of the electronic portion 110 with the plurality of connectors 125. The elongate member 150 may include a stop (not shown) to limit the travel distance of the screen 120.

The side 160 (FIG. 5C) of the electronic portion 110 that is exposed when the screen 120 is moved may be tilted as shown in FIG. 5C, to provide easier access to the plurality of connectors 125. The side 160 of the electronic portion 110 may be tilted from the normal by about 10-15 degrees.

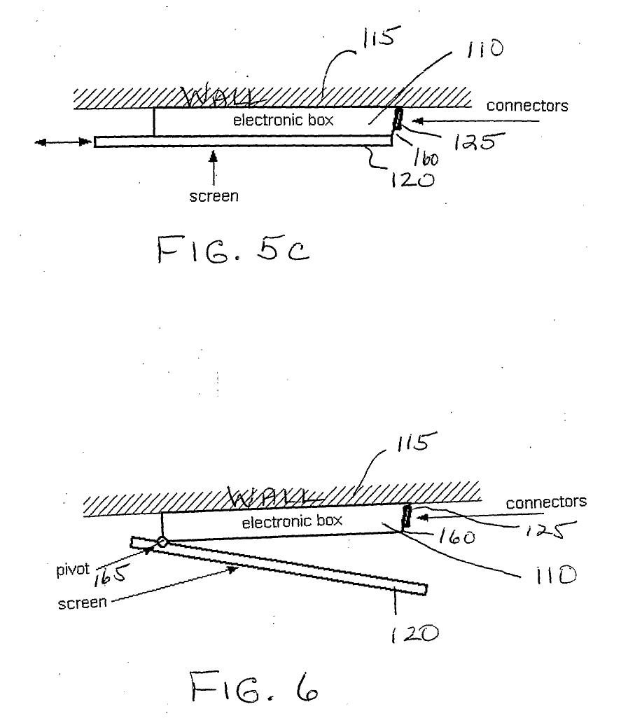

Referring to FIG. 6, the screen 120 may optionally be moveable by pivoting it at an angle away from the wall 115 upon which the display device is mounted. The screen 120 is coupled to a side of the electronic portion 110 with a hinge 165. The hinge 165 permits the screen 120 to be pivoted away from the electronic portion 110. The screen 120 is pivotable at an angle sufficient to provide easy access to the connectors needed to couple a remote appliance to the display device. A blocking member should be included on the hinge to limit its pivot as well as to restrict the swing-out angle of the screen 120.

The side 160 of the electronic portion 110 that is exposed when the screen 120 is pivoted may be tilted as shown in FIG. 6, to provide easier access to the plurality of connectors 125. The side 160 of the electronic portion 110 may be tilted from the normal by about 10-15 degrees.

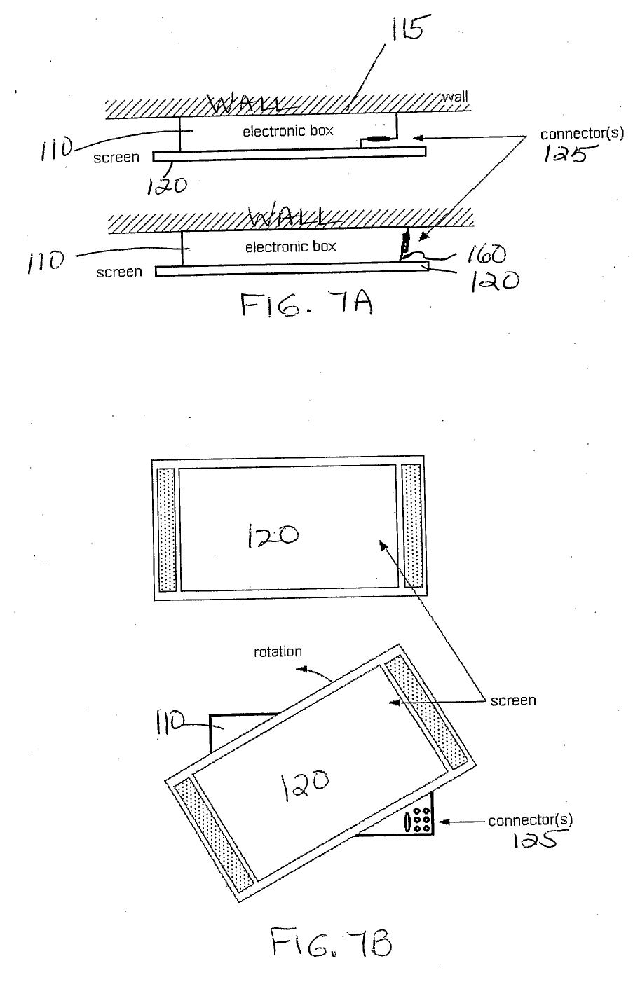

Referring to FIGS. 7A-7B, the screen of the display device may be rotatable with respect to the electronics portion 110 of the display device. In one embodiment, the screen 120 is rotatable in a vertical plane with respect to the electronics portion 110 of the display device. The screen is rotatable to provide easier access to the connectors 125 needed to couple a remote appliance to the display device.

Referring to FIG. 7A, a top view of the wall mounted display device 100 is shown. The wall mounted display device 100 includes an electronic portion 110 and a screen 120 mounted on a wall 115 of a room. The electronic portion 110 includes electronic parts of the display device necessary to display images on the screen 120. The electronic portion 110 has a plurality of connectors 125 coupled to a side thereof (FIG. 5C). The screen 120 is coupled to the electronic portion 110 with at least one rotatable member (not shown) and rollers (not shown). Alternatively, sliders, wheels or ball bearings may be used instead of rollers to provide easy movement along the at least one rotatable member.

The screen 120 is rotatable so that easy access is provided to the plurality of connectors 125 coupled to the side of the electronic portion 110, or optionally facing the viewer. The screen 120 is preferably rotatable a distance sufficient to expose the side of the electronic portion 110 with the plurality of connectors 125. The rotatable member may include a stop (not shown) to limit the rotation of the screen 120. Depending on the position and size of the connectors 125, a screen should preferably have a rotation angle of about 30-60 degrees.

The side 160 of the electronic portion 110 that is exposed when the screen 120 is rotated may be tilted as shown in FIG. 7A, to provide easier access to the plurality of connectors 125. The side 160 of the electronic portion 110 may be tilted from the normal by about 10-15 degrees.

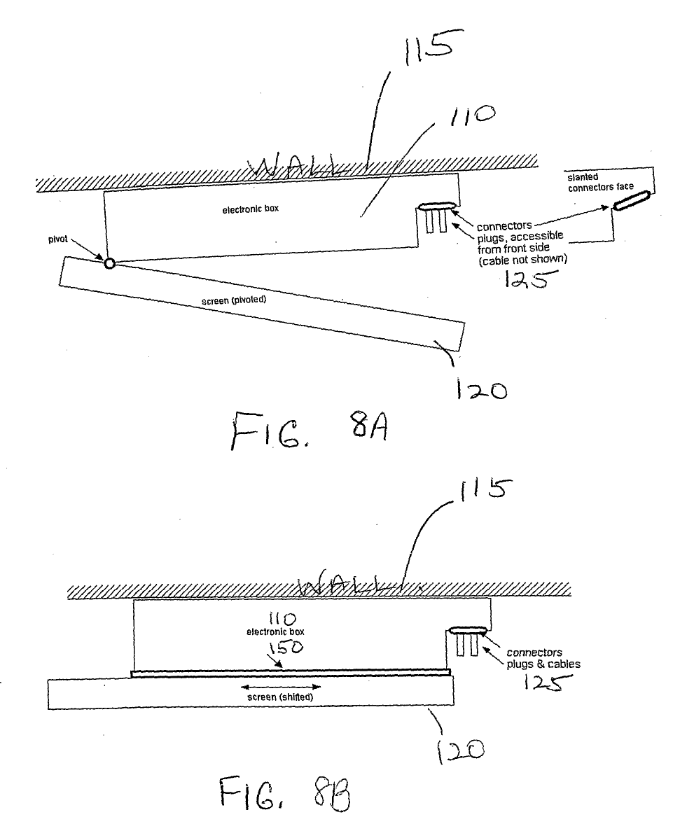

FIGS. 8A-8B show alternative connector positions for the plurality of connectors 125. Referring to FIG. 8A, the plurality of connectors 125 are positioned along a front edge of the electronic portion 110 away from the hinge 165 shown in FIG. 6. The connector region may optionally be tilted to provide easier access to the plurality of connectors 125. The connector region may be tilted from the normal by about 10-15 degrees.

Referring to FIG. 8B, the plurality of connectors 125 are positioned along a front edge of the electronic portion 110 that is exposed when the screen 120 is moved as shown in FIG. 5C. The connector region may optionally be tilted to provide easier access to the plurality of connectors 125. The connector region may be tilted from the normal by about 10-15 degrees.

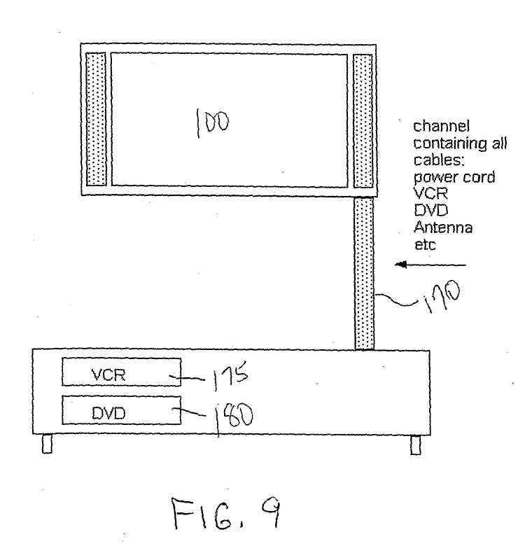

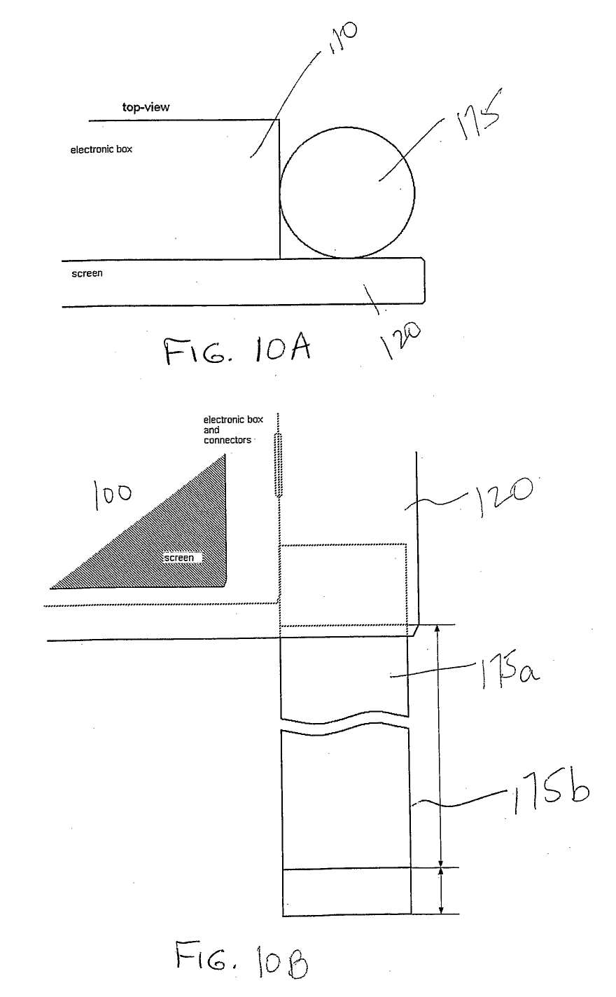

FIG. 9 shows a front view of the wall mounted display device 100 having a conduit 170 within which is hidden the wires (not shown) coupling the display device with one or more remote appliances 175, 180. FIGS. 10A-10B show enlarged top and front views of the conduit 170 shown in FIG. 9. The conduit 175 may match the design of the display device 100, so as to cover the wires coupling the display with remote appliances in a fashionable manner.

The conduit 175 may be removable and have any suitable shape. Suitable shapes for the conduit 175 may include round and square among others. The conduit is preferably coupled to the display device 100 where the connectors 125 are located. The conduit 175 may have a variable length (telescope-like) by combining several pieces of material.

Referring to FIGS. 10A-10B, a round conduit 175 is shown encasing the wires. A short part of the conduit 175a may be mounted to the display and then one or more elongation parts 175b attached thereto. The several parts may be connected with any suitable mechanism such as a snap mechanism, a rotating mechanism, as well as friction.

The foregoing illustrates some of the possibilities for practicing the invention. Many other embodiments are possible within the scope and spirit of the invention. It is, therefore, intended that the foregoing description be regarded as illustrative rather than limiting, and that the scope of the invention is given by the appended claims together with their full range of equivalents.

1. A wall mountable display device, comprising:
a flat screen,
an electronic portion, wherein the electronic portion includes a connector portion having a plurality of connectors; and
wherein the connector portion is moveable with respect to the electronic portion.

2. The display device of claim 1 wherein the connector portion includes at least one slot.

3. The display device of claim 1 wherein the connector portion includes at least one guiding member moveable in a slot of the electronic portion.

4. The display device of claim 2 wherein the at least one slot is one of linear and curved.

5. The display device of claim 2 wherein the electronic portion includes one or more openings that correspond with the at least one slot in the connector portion.

6. The display device of claim 5 wherein one or more guiding member couples each of the one or more openings with each, of the at least one slot.

7. The display device of claim 2 wherein two or more of the at least one slot have different lengths so as to tilt the connector portion at an angle toward the screen when the connector portion is moved.

8. The display device of claim 1 wherein a side of the connector portion having the plurality of connectors is angled toward the screen.

9. A wall mountable display device, comprising:
a flat screen,
an electronic portion, wherein the electronic portion includes a plurality of connectors; and
wherein the screen is moveable with respect to the electronic portion.

10. The display device of claim 9 wherein at least one elongate member and a plurality of rollers couple the screen to the electronic portion and cooperate to move the screen with respect to the electronic portion.

11. The display device of claim 10 wherein the at least one elongate member includes a stop to limit the travel distance of the screen.

12. The display device of claim 9 wherein a side of the electronic portion having the plurality of connectors is angled toward the screen.

13. The display device of claim 9 wherein a side of the electronic portion having the plurality of connectors is parallel to the screen.

14. A wall mountable display device, comprising:
a flat screen,
an electronic portion, wherein the electronic portion includes a plurality of connectors; and
wherein the screen is pivotable with respect to the electronic portion.

15. The display device of claim 14 wherein a hinge couples the screen to the electronic portion and cooperates to pivot the screen with respect to the electronic portion.

16. The display device of claim 15 wherein the hinge includes a stop to limit the pivot angle of the screen.

17. The display device of claim 14 wherein a side of the electronic portion having the plurality of connectors is angled toward the screen.

18. The display device of claim 14 wherein a side of the electronic portion having the plurality of connectors is parallel to the screen.

19. A wall mountable display device comprising:
a flat screen;
an electric portion, wherein the electronic portion includes a plurality of connectors; and
a cable conduit, wherein the cable conduit extends beyond the display device.

20. The display device of claim 19 wherein the cable conduit is detachable.

21. The display device of claim 19 wherein the cable conduit is elongate.

22. A wall mountable display device, comprising:
a flat screen;
an electronic portion, wherein the electronic portion includes a connector portion having a plurality of connectors; and
wherein the screen is rotatable in a vertical plane.

23. The display device of claim 22 wherein rotation of the screen is limited by a stop.

24. The display device of claim 22 wherein the screen rotates at an angle less than about 60 degrees.
